(19) United States
(12) Patent Application Publication
(10) Pub. No.: US 2013/0120916 A1
(43) Pub. Date: May 16, 2013

(54) COATING COMPOSITIONS AND METHODS FOR COATING NETWORK PROTECTOR AND SAFETY SWITCH HOUSINGS

(71) Applicant: EATON CORPORATION, Cleveland, OH (US)

(72) Inventors: Richard James LESLIE, New Baltimore, MI (US); Alaa Abdel-Azim ELMOURSI, Troy, MI (US); Randal D. GAZDECKI, Cleveland, TN (US); Stephen William ONEUFER, Hope Mills, NC (US)

(73) Assignee: EATON CORPORATION, Cleveland, OH (US)

(21) Appl. No.: 13/670,545

(22) Filed: Nov. 7, 2012

Related U.S. Application Data
(63) Continuation-in-part of application No. 13/296,587, filed on Nov. 15, 2011.

(51) Int. Cl. H05K 5/02; B05D 5/12

(52) U.S. Cl. CPC H05K 5/02; B05D 5/12; B82Y 99/00
USPC 361/679.01; 427/58; 977/773

(57) ABSTRACT

The disclosed concept pertains to coating compositions, methods of preparing the coating compositions, methods of applying the coating compositions to form a coating on a component in an electrical system, and the coated components produced therefrom. The methods include obtaining an uncoated component having an interior surface and an exterior surface, and at least partially applying to at least one of said interior surface and said exterior surface of the uncoated component a coating composition to form a coating thereon. The coating composition includes a binder material and nanoparticles. The component can include a network protector housing or safety switch housing.

### CROSS REFERENCE To RELATED APPLICATION

This is a Continuation-In-Part (CIP) Application which claims the benefit of priority to U.S. patent applications having Ser. Nos. 13/270,427 and 13/296,587, filed in the United States Patent and Trademark Office on Oct. 11, 2011 and Nov. 15, 2011, respectively, and currently pending. These U.S. Patent Applications are incorporated herein by reference in their entirety.

### BACKGROUND

1. Field.

The disclosed concept pertains generally to coating compositions, methods for preparing the compositions, methods for applying the compositions to substrates to form coatings thereon, and the coated articles produced therefrom. In particular, the disclosed concept pertains to coating and/or coated components in electrical systems. The components including network protector and safety switch housings. The electrical systems including electricity distribution systems.

2. Background

Network protectors are used in electricity distribution systems. A network protector automatically connects and disconnects an associated power transformer from a network when power starts flowing in a reverse direction. Typically, the network protector is set to close when the voltage difference and phase angle are such that the transformer will supply power to a secondary grid. Conversely the network protector is set to open when the voltage difference and phasing angle is such that the secondary grid would back-feed through the transformer and supply power to the primary circuit.

Network protectors may be located in a specific National Electrical Manufacturers Association (NEMA) environment, such as underground vaults. Network protectors that are located in underground vaults may be exposed to moisture, sewage, dirt, small animals, and other contaminants. To protect the stability and dependency of the secondary grid, the network protector should be able to withstand a harsh environment. To provide protection against a harsh environment, the network protectors are often enclosed in housings made of corrosion resistant epoxy coated steel or corrosion resistant stainless steel.

Safety switches are used to provide a point of local electrical disconnect in a specific NEMA environment, such as food processing. Safety switches are provided so that an end load can be maintained, repaired, or replaced safely down circuit when power to the end load is disconnected by a locked-off switch. Many industries require that the safety switch be located “in-sight” of operators of the equipment protected by the safety switch. This means that the safety switch is regularly exposed to materials being processed as well as disinfectants used to clean the equipment. The safety switch includes one or more sets of electrical contacts that are enclosed in a housing to provide protection against a harsh environment. The primary purpose of the safety switch is to provide a local on-off switch that has a long life span in a corrosive environment e.g., NEMA 4X 316 stainless steel corrosion resistance).

The housings for the network protectors and safety switches can be made from a variety of materials including metals and metal alloys, ceramics, cements, plastics and composites thereof. The composites can be composed of, for example, metal-, masonry-, or polymer-based products. The surfaces of the housings that are exposed to the environment may come into contact with a variety of agents, including dust, moisture, water, and oils. In industrial applications, the surfaces may be exposed to a variety of agents such as water, aqueous salt solutions, solutions of aqueous acid or base, and chemicals that may be dissolved or suspended in aqueous compositions or other liquids that are used in manufacturing processes. Further, the temperatures to which the surfaces are exposed can vary. Elevated temperatures, for example, can accelerate degradation processes, such as corrosion or leaching effects.

If the housing for a network protector or safety switch is not manufactured of a material that is corrosion resistant, the housing itself will not provide appropriate protection of the network protector or safety switch against a harsh environment. Thus, the housing which is not constructed of corrosion resistant material can have applied thereto a coating composition which forms a corrosion resistant coating thereon. Further, even if the housing is manufactured of a corrosion resistant material, improved protection against a harsh environment can be provided by applying the corrosion resistant coating to at least one of an interior surface and exterior surface of the housing in accordance with the disclosed concept.

### SUMMARY

These needs and others are met by embodiments of the disclosed concept, which provide methods for coating components in an electrical system, and the coated components resulting therefrom.

In an aspect of the disclosed concept, a method of at least partially coating a component in an electrical system is provided. The method includes obtaining an uncoated component having an interior surface and an exterior surface, and at least partially applying to at least one of said interior surface and said exterior surface of the uncoated component a coating composition to form a coating thereon. The coating composition including polyurethane.

In certain embodiments, the component is selected from the group consisting of a network protector housing and safety switch housing.

In certain embodiments, the coating composition further includes aliphatic diisocyanate, such as hexamethylene diisocyanate, and/or amine, such as triethylamine.

In another aspect of the disclosed concept, an at least partially coated component in an electrical system is provided. The at least partially coated component includes an uncoated having an interior surface and an exterior surface, and a coating composition including polyurethane. The coating composition is at least partially applied to at least one of the interior surface and the exterior surface.

In still another aspect of the disclosed concept, a coated apparatus is provided. The apparatus includes a housing having an interior surface and an exterior surface. The housing is structured to enclose a component selected from the group consisting of a network protector and a safety switch. The housing has a coating formed on at least one of the interior surface and the exterior surface. The coating is formed from a coating composition including polyurethane.

### BRIEF DESCRIPTION OF THE DRAWINGS

A full understanding of the disclosed concept can be gained from the following description of the preferred embodiments when read in conjunction with the accompanying drawings in which:

FIG. 1 is an isometric view of a network protector enclosure in accordance with an embodiment of the disclosed concept.

FIG. 2 is an isometric view of a safety switch enclosure in accordance with an embodiment of the disclosed concept.

FIG. 3 is a diagram of the contact angle between a droplet of liquid and a coated component in accordance with an embodiment of the disclosed concept.

FIG. 4 is diagram of a coated component in accordance with an embodiment of the disclosed concept.

### DESCRIPTION OF THE PREFERRED EMBODIMENTS

The disclosed concept includes coating compositions, methods of preparing the coating compositions and methods of applying the coating compositions to components in electrical systems, and the coated components produced therefrom. The coating compositions include super repellent coatings.

Directional phrases used herein and the claims, such as, for example, “left,” “right,” “top,” “bottom,” “upper,” “lower,” “front,” “back,” “forward.,” “above,” “below,” “clockwise,” “counter clockwise” and derivatives thereof, relate to the orientation of the elements shown in the drawings and are not limiting to the claims unless expressly recited therein.

As employed herein and the claims, the statement that two or more parts are “coupled” or “connected” together shall mean that the parts are joined together either directly or joined through one or more intermediate parts.

As employed herein and the claims, the term “number” means one or an integer greater than one (i.e., a plurality).

As employed herein and the claims, the term “housing” means the enclosure that encompasses or houses each of the network protector and the safety switch, and shall include the door and the casing around the door that provides access to the interior of the housing.

As employed herein and the claims, the term “hydrophobic” and related terms, such as “hydrophobicity”, when referring to a surface or a border means one that results in a water droplet forming a surface contact angle of about 90 degrees or greater and less than about 150 degrees at room temperature (e.g., a temperature from about 18° C. to about 23° C.).

As employed herein and the claims, the term “superhydrophobic” and related terms, such as “superhydrophobicity”, when referring to a surface or a border means one that results in a water droplet forming a surface contact angle of about 150 degrees or greater and less than the theoretical maximum contact angle of about 180 degrees at room temperature (e.g., a temperature from about 118° C. to about 23° C.). For the purposes of this disclosure, the term “hydrophobic” and related terms, such as “hydrophobicity”, includes “superhydrophobic” and “superhydrophobicity” unless stated otherwise.

As employed herein and the claims, the term “oleophobic” and related terms, such as “oleophobicity”, when referring to a material or surface means one that results in a droplet of light mineral oil forming a surface contact angle of about 25 degrees or greater and less than the theoretical maximum contact angle of about 180 degrees at room temperature (e.g., a temperature from about 18° C. to about 23° C).

The term “alkyl” as used herein and the claims, denotes a linear or branched alkyl radical. Alkyl groups may be independently selected from C₁ to C₂₀ alkyl, C₂ to C₂₀ alkyl, C₄ to C₂₀ alkyl, C₆ to C₁₈ alkyl, C₆ to C₁₆ alkyl, or C₆ to C20 alkyl.

For the purposes of this disclosure, when content is indicated as being present on a “weight basis” the content is measured as the percentage of the weight of components indicated, relative to the total weight of the hinder system or composition.

For ease of description, the disclosed concept is described herein in association with network protector enclosures and safety switch enclosures for electrical distribution systems. However, the disclosed concept is applicable for coating a wide range of electrical equipment and systems.

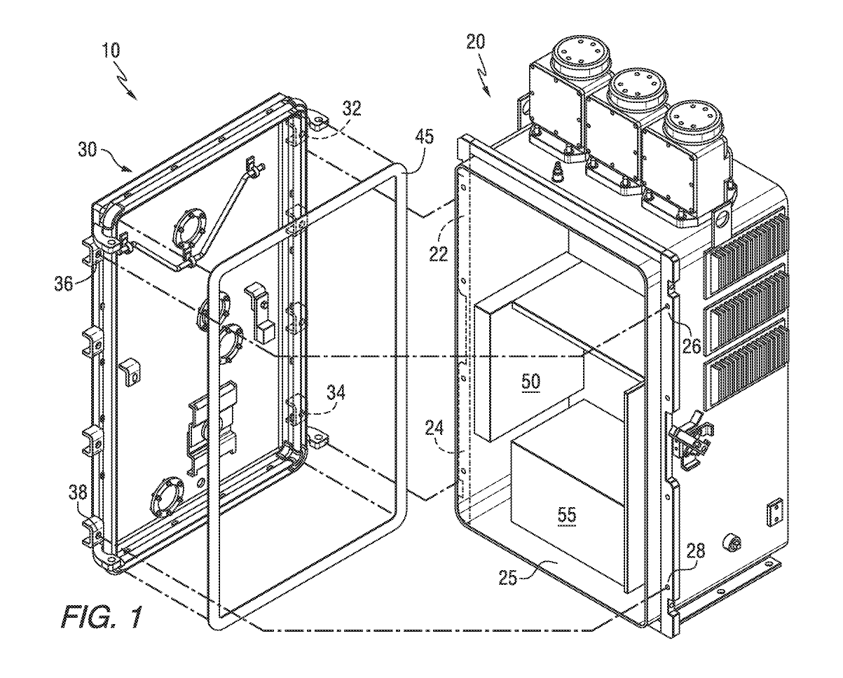

FIG. 1 shows network protector housing 10 in accordance with certain embodiments of the disclosed concept. The housing 10 includes a rear portion 20 and a cutout or a front opening 25. The front opening 25 provides access to the interior of the rear portion 20. To cover the front opening 25, the housing 10 includes a door or an access panel 30 attached to the rear portion 20. The access panel 30 is configured to be larger than the front opening 25 of the housing 10. Therefore, the access panel 30 covers the front opening 25 as well as portion of the rear portion 20.

The access panel 30 may be attached to a face of the rear portion 20 in a manner that allows the access panel 30 to be removed from the rear portion 20. As shown in FIG. 1, in accordance with certain embodiments, the housing 10 is configured with housing frame components 22, 24, 26, and 28. The housing frame components 22, 24, 26, and 28 correspond to access panel frame components 32, 34, 36, and 38. The housing frame components 22, 24, 26, and 28 are configured to be secured to the access panel frame components 32, 34, 36, and 38. The housing frame components 22, 24, 26, and 28 may be secured to the access panel frame components 32, 34, 36, and 38 with fasteners. A wide variety of conventional fasteners which are known in the art may be employed, such as but not limited to nails, screws, bolts, latches.

The housing 10 may be constructed of various materials known in the art, such as metal, metal alloy, ceramic, cement, plastic and composites thereof in accordance with certain embodiments of the disclosed concept, an interior and/or exterior surface of the housing 10 is coated with a super repellent coating as will be described in more detail below.

As shown in FIG. 1, an electrical relay setup 50 is placed in the rear portion 20 of the housing 10 to protect the relay setup 50 from contaminants (e.g., fluids, water, sewage, and the like). The relay setup 50 is accessed through the front opening 25 when the access panel 30 is open. A mechanism 55 is also placed in the rear portion 20 to be protected from the contaminants. While one particular combination of an electrical relay setup 50 and mechanism 55 is illustrated in FIG. 1, any number of combinations of electrical relays, mechanisms, and other devices (e.g., circuit breakers, contacts, sensors, circuits, and the like) may be enclosed in the rear portion 20 of the housing 10.

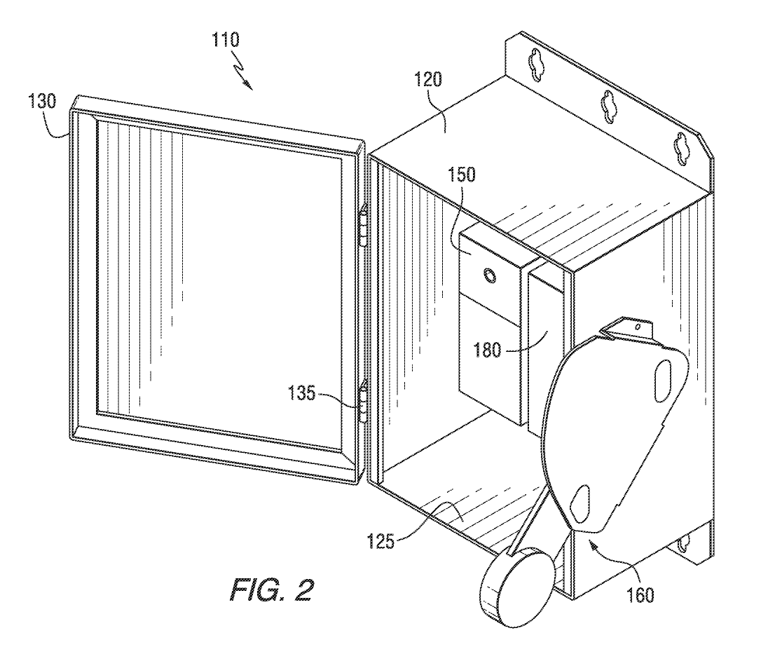

Referring to FIG. 2, an example embodiment of a safety switch housing 110 is illustrated. The housing 110 includes a rear portion 120 and a cutout or front opening 125. The front opening 125 provides access to the interior of the rear portion 120. To cover the front opening 125, the housing 110 includes a door or an access panel 130 attached to the rear portion 120. The access panel 130 is configured to be larger than the front opening 125. Therefore, the access panel 130 covers the front opening 125 as well as portion of the rear portion 120. As shown in FIG. 2, in accordance with certain, embodiments, the access panel 130 is attached to a face of the rear portion 120 with at least one access panel hinge 135 that allows the access panel 130 to pivot open. In the manner of a door. In certain embodiments, a plurality of access panel hinges can be employed. In FIG. 2, the access panel 130 is attached to the rear portion 120 at one side of the access panel 130. Alternatively, the access panel 130 may be attached to the rear portion 120 by the access panel hinge 135 at the top or bottom of the access panel 130. Further, as an alternative to an access panel hinge 135, the access panel 130 may be secured to the rear portion 120 with a wide variety of conventional fasteners known in the art, such as but not limited to nails, screws, bolts, latches, and the like.

The rear portion 120 of the safety switch housing 110 includes a switch handle 160, a switching mechanism 180, and an electrical contractor set 150. The switching mechanism 180 and electrical contractor set 150 are located within the interior of the rear portion 120. The switch handle 160 is located on the exterior of the rear portion 120 and is mechanically coupled to the switching mechanism 180 through the wall of the rear portion 120. The switching mechanism 180 opens or closes the electrical contractor set 150 in response to rotation of the switch handle 160.

The electrical contractor set 150 is placed in the rear portion 120 of the housing 110 to provide protection from processing materials. The switch handle 160 may be rotated to open or close the electrical contractor set 150 without opening the access panel 130. The electrical contractor set 150 is accessed through the front opening 125 when the access panel 130 is open. While one particular combination of a switch handle 160, switching mechanism 180, and electrical contractor set 150 is illustrated in FIG. 2, any number of combinations of handle types, switching mechanisms, and contractor sets may be enclosed by a housing that employs a super repellant coating.

In accordance with the disclosed concept, a coating composition is applied to an interior surface and/or an exterior surface of a substrate, e.g., housing for network protector or safety switch, to form a highly durable coating and/or surface treatment thereon. The coating and/or surface treatment imparts a variety of desirable characteristics to the substrate and its surface, including at least one of hydrophobicity, superhydrophobicity and oleophobicity. These characteristics can result in the component and its surface exhibiting a variety of desirable properties. These properties can include, but are not limited to, resistance to wetting, corrosion, cracking or warping, exfoliation, fouling and dust or dirt accumulation on surfaces. In the art, the term “self-cleaning” may be used to describe resistance to dust or dirt accumulation. Further, the coating and/or surface treatment can provide hydrophobicity, superhydrophobicity and oleophobicity while also resisting mechanical abrasion.

In certain embodiments of the disclosed concept, the coating formed by application of the coating composition exhibits super repellency which causes liquids, such as water and oil, to bead up on a coated surface and exhibit a contact angle as above-defined for each of the terms “hydrophobic”, “superhydrophobic” and “oleophobic”, and a roll-off angle of about 10 degrees or less. In forming such a contact angle with a coated surface, the coated surface does not wet and is considered to he self-cleaning. This property is referred to in the art as the Lotus effect. Without intending to be bound by any particular theory, it is believed that the Lotus effect refers to the very high water repellency (e.g., superhydrophobicity) exhibited by the leaves of a lotus flower. Dirt particles are picked up by water droplets due to a complex microscopic and nanoscopic architecture of the surface which minimizes adhesion. Due to their high surface tension, water droplets tend to minimize their surface trying to achieve a spherical shape. On contact with a surface, adhesion forces result in wetting of the surface. Either complete or incomplete wetting may occur depending on the structure of the surface and the fluid tension of the droplet.

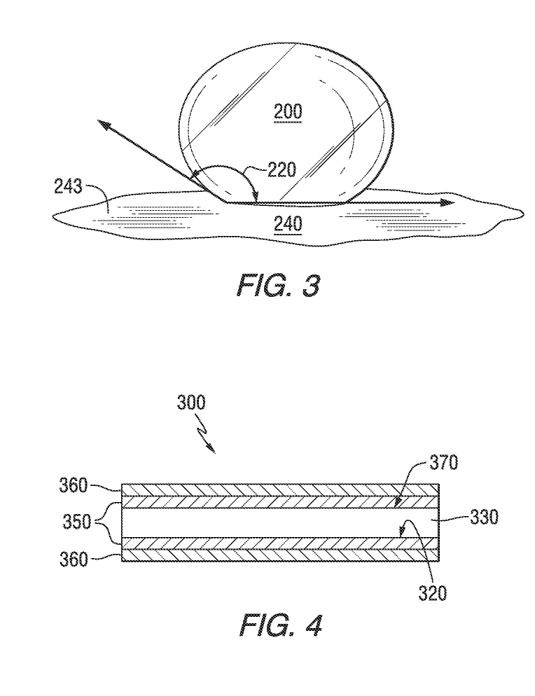

FIG. 3 illustrates a diagram of the contact angle 220 between a droplet of liquid 200 and a coated substrate 240. The coated substrate 240 includes a super repellant coating 243. The coating 243 may be hydrophobic, superhydrophobic, or oleophobic. The coating 243 is designed to repel liquid, such as water or oil. Accordingly, the droplet of liquid 200 beads up on the surface of the coated substrate 240. By beading up, the contact angle 220 between the coated substrate 240 and the droplet of liquid 200 is increased. For example, a droplet of liquid 200 may exhibit a contact angle 220 of 150° or greater with the coated substrate 240 and have a roll-off angle of less than 10°. The greater the contact angle 220 between the coated substrate 240 and the droplet of liquid 200, the more likely the droplet of liquid 200 is to roll off the coated substrate 240.

Further, without being bound by any particular theory, it is believed that the cause of the self-cleaning property of the coated substrate is the hydrophobic water-repellent double structure of the surface. This enables the contact area and the adhesion force between surface and droplet to be significantly reduced, resulting in a self-cleaning surface. Thus, dirt particles with a reduced contact area are picked up by water droplets and are easily cleaned off the surface. If a water droplet rolls across a contaminated surface (e.g., surface containing dirt particles), the adhesion between a dirt particle, irrespective of its chemistry, and the droplet is higher than between the particle and the surface,

In accordance with the disclosed concept, at least one of an interior surface and exterior surface of an electrical component, such as, a housing for a network protector or safety switch is coated with a super repellant coating. The super repellant coating may be hydrophobic, superhydrophobic or oleophobic. The super repellant coatings are formed by at least partially applying a coating composition to at least one of the interior and exterior surfaces of the housing. The coating composition can be water-based or solvent-based. Both of the water-based and solvent-based coating compositions include a binder material and nanoparticles that provide for super repellent properties.

Suitable binder materials can be selected from a wide variety of known materials in the art and can include essentially any binder that is capable of adhering to the surface to be coated and retaining the nanoparticles.

In certain embodiments, the binder material may be selected from known lacquers, polyurethanes, fluoropolymers, epoxies, or powder coatings (e.g., thertnoplastics). In other embodiments the binder material may be selected a lacquer, polyurethane, fluoropolymer, or thermoplastic. The binder material may be hydrophilic, hydrophobic or superhydrophobic “as applied.” For the purposes of this disclosure, when the binder material or its properties are described “as applied,” it is understood that the binder material and its properties are being described in the absence of the nanoparticles (described herein) that may alter the durability, hydrophobic/superhydrophobic and oleophobic properties of the binder material.

In certain embodiments of the disclosed concept, the binder material includes polyurethane. In general, polyurethanes are polymers consisting of a chain of organic units joined by urethane (carbamate) linkages. Polyurethane polymers are typically formed through polymerization of at least one type of monomer containing at least two isocyanate functional groups with at least one other monomer containing at least two hydroxyl (OH) groups. A catalyst may be employed to speed the polymerization reaction. Other components may be present in the polyurethane coating compositions including, but not limited to surfactants and other additives that bring about the carbamate forming reaction(s) which yield a coating having the desired properties in a desired cure time.

In certain embodiments, the polyurethane employed may be formed from a polyisocyanate and a mixture of OH— and amine (NH)— terminated monomers, in such systems, for example, the polyisocyanate can be a trimer or homopolymer of hexamethylene diisocyanate, and the amine can be triethylamine.

Solvents which are compatible with such systems are known in the art and non-limiting examples include but are not limited to n-butyl acetate, toluene, xylene, ethyl benzene, cyclohexanone, isopropyl acetate, methyl isobutyl ketone and mixtures thereof, as well as other solvents disclosed herein.

In certain embodiments, a wide variety of commercially available polyurethanes may be used to prepare the super repellent coating compositions described herein. Polyurethanes may be obtained as a single component ready-to-apply composition or as a two- or three-part (component) system.

Non-limiting examples of suitable coating compositions for use in certain embodiments of this disclosed concept include solvent-based I-Coat formulations, such as but not limited to 1-Flex, E-Coat formulations, and water-based NuO Coat formulations, either with or without acetone, which are currently manufactured and commercially available from Ross Nanotechnology, LLC. It is also contemplated that future formulations related to these products may be suitable for use in the disclosed concept. Further, suitable coating compositions for use in certain embodiments of the disclosed concept include those described in United States Patent Application Publication 2012/0045954 A1 which is incorporated herein by reference.

In certain embodiments, the binder material is not comprised of materials monomers and oligomers) that polymerize when exposed to ultraviolet (UV) light to form polymers. In other embodiments, the binder material is not comprised of thermoset polymeric materials.

As previously indicated, a consideration in selecting a suitable binder material for use in the compositions of the disclosed concept is the compatibility between the surface to be coated and any solvent(s) used to apply the binder material to the surface. For example, polyurethane coatings are compatible with, and show good adhesion to, a wide variety of surfaces including but not limited to, those of metals, glass, ceramics, concrete, wood, and plastics. Other considerations include the environment to which the coating will be exposed after it is applied to a substrate.

The coating compositions of the disclosed concept can be applied to a surface of the substrate, e.g., housings, using various conventional techniques in the art. The coating compositions can be applied using single-step processes or multiple-step processes. Within each of these processes, the coating compositions can be applied to the substrate by spraying, rolling, brushing, dipping, and the like. In certain embodiments, the coating composition can be applied by thermal deposition processes.

As aforementioned, in addition to the binder material, the coating compositions of the disclosed concept include nanoparticles. In certain embodiments, the nanoparticles are incorporated, e.g., dispersed, in the binder material prior to application of the coating composition to a substrate. The binder material may include micron particles and the nanoparticles may be dispersed within the micron particles. The binder material and nanoparticle-containing composition is applied to or deposited on an interior surface or an exterior surface or both surfaces of a housing for a network protector or a safety switch to form a coating (e.g., film or layer) on the surface(s). This process is referred to as a one-step process. Alternatively, in a multiple-step process, coating as described can serve as a basecoat or first layer and subsequently, a nanoparticle-containing composition can be applied thereto to form a topcoat or second layer. The result is a two-layer coating wherein there is a thin layer of nanoparticles on top of the binder material/nanoparticle layer. Thus, in this embodiment, both the first layer and the second layer include the presence of nanoparticles therein. The nanoparticles in the binder material and topcoat may be the same or different.

In alternate embodiments of the multi-step process, wherein a two-layer coating is applied, the binder material forming the basecoat or first layer may not include the addition of nanoparticles thereto. Thus, only the topcoat or second layer may include nanoparticles.

Further, in certain embodiments, the surface of the substrate may be subjected to a preparation process prior to applying or depositing the coating composition of the disclosed concept. The preparation process can include a pre-coating or pre-treatment to the substrate to facilitate or enhance applying and/or adhesion of the binder material thereto. For example, the preparation process can include applying a catalyst or catalyst-containing composition to the surface of the substrate prior to applying the binder material, such that the binder material is applied onto the catalyst.

The coatings formed from the compositions containing the binder material and nanoparticles can have a broad range of thicknesses. In some embodiments the coatings will have a thickness in a range of from about 10 microns to about 225 microns; about 15 microns to about 200 microns; about 20 microns to about 150 microns; about 30 microns to about 175 microns; or about 50 microns to about 200 microns.

The basecoat including the binder material and optionally nanoparticles dispersed therein can also include other additives that are known in the coatings art. For example, the basecoat may contain solvent(s) as described herein.

The optional topcoat including the nanoparticles can also include other additives that are known in the coatings art. For example, in certain embodiments the topcoat can include at least one of an alkyl-containing compound, for example, alkane, such as hexane, and filler, such as silica.

FIG. 4 shows a coated substrate 300 in accordance with certain embodiments of the disclosed concept. As above-described, the substrate 300 can be a coated enclosure for a network protector or safety switch. The coated substrate 300 includes a substrate (uncoated) 330 having an exterior surface 320 and an interior surface 370. A base coating 350 is applied to each of the exterior surface 320 and the interior surface 370. A top coating 360 is applied to the base coating 350 which is applied to the exterior surface 320 and the interior surface 370. As described herein, the composition of the base coating 350 can include a binder material or a combination of a binder material and nanoparticles dispersed therein, and the composition of the top coating 360 can include nanoparticles. Thus, nanoparticles can be present in both the base coating 350 and the top coating 360 or only in the top coating 360. In alternate embodiments wherein the base coating 350 includes the presence of nanoparticles, the top coating 360 may be optional.

When the substrate 330 is a housing 10,110 (as shown in FIGS. 1 and 2), applying the base coating 350 and the top coating 360 to the exterior surface 320 of the substrate 330 reduces the likelihood of contaminants (e.g., fluids, water, sewage, and the like) from entering the housing 10,110 due to the anti-wicking properties exhibited by the super repellant base and top coatings 350,360. The base coating 350 and top coating 360 may be applied to the housing 10,110 before or after its installation. Further, the base coating 350 and top coating 360 may be applied to the rear portion 20,120 through the opening 25,125 of the housing 10,110 (as shown in FIGS. 1 and 2).

In certain embodiments, not shown in FIG. 4, the substrate 330 can include only the base coating 350 applied thereto (in the absence of the top coating 360 applied to the base coating 350). In these embodiments, the base coating 350 includes a combination of binder material and nanoparticles dispersed therein.

In certain embodiments, not shown in FIG. 4, the substrate 330 can include the top coating 360 and/or the base coating 350 applied only to one of the exterior surface 320 or the interior surface 370.

In certain embodiments, suitable coating compositions for use in the disclosed concept can include the following compositions. A three-part coating composition may be employed wherein Part A is a catalyst, Part B is a polymer-containing binder and Part C is an alkane-containing top coat. The catalyst can be applied to at least one of the interior surface and exterior surface of a substrate, e.g., housing. The polymer-containing binder material can be applied onto the catalyst, and subsequently, the alkane-containing top coat can be applied onto the coating or layer formed by the polymer-containing binder material. The top coat can be applied while the polymer-containing binder coating is still tacky, e.g., prior to drying. This coating composition includes the ingredients in the amounts listed below, and can be commercially obtained under the trade name NeverWet™ I Flex from Ross Technology, LLC.

I. CATALYST-PART A

| Ingredient | % by Wt |
|---|---|
| n-Butyl Acetate | 12 |
| Xylene | 12 |
| Hexamethylene Diisocyanate Polymer | 75 |
| Hexamethylene Diisocyanate | 0.7 max |

I. POLYMER-CONTAINING BINDER MATERIAL-PART-B

| Ingredient | % by Wt |
|---|---|
| Isopropyl Acetate | 37 |
| n-Butyl Acetate | 37 |
| Polymeric Resin | 20 |
| Polymeric Particles | 5 |

I. ALKANE-CONTAINING TOP COAT-PART C

| Ingredient | % by Wt |
|---|---|
| Hexane | 98 |
| Silica | 2 |
| Additive | <1 |

In certain embodiments, a single-coat coating composition may be employed. This composition is applied to at least one of the interior surface and exterior surface of a substrate, e.g., housing. This composition includes the ingredients in the amounts listed below, and can be obtained under the trade name NeverWet™ NuO in a spray can application from Ross Nanotechnology, LLC. In this embodiment, the following ingredients are combined and applied to the substrate as a single coating composition to form a one-layer coating.

II. SINGLE COAT

| Ingredient | % by Wt |
|---|---|
| Acetone | 20-25 |
| N-Methyl-2pyrolidone (NMP) | 4-6 |
| Triethylamine (TEA) | <1 |
| 2-(2-Butoxyethoxy)-ethanol | <1 |
| Dibutyl Phthalate | <1 |
| TiO₂ | 1-2 |
| Polymer Particle | 2-4 |
| Silane reacted with silicon dioxide | 4-6 |
| Polymer | 10-20 |
| Water | Balance |

The above coating composition can also be obtained without the presence of acetone. This coating composition includes the ingredients in the amounts listed below, and can be obtained under the trade name NeverWet™ NuO from Ross Nanotechnology,

III. W/O ACETONE

| Ingredient | % by Wt |
|---|---|
| N-Methyl-2pyrolidone (NMP) | 2-4 |
| Triethylamine (TEA) | <1 |
| 2-(2-Butoxyethoxy)-ethanol | 1 |
| Dibutyl Phthalate | <1 |
| TiO₂ | 3-7 |
| Polymer Particle | 2-4 |
| Silane reacted with silicon dioxide | 4-6 |
| Polymer | 10-20 |
| Water | Balance |

In certain embodiments, the following three-part coating composition may be employed wherein Part A is a catalyst, Part B is a polymer-containing binder and Part C is an alkane-containing top coat. The catalyst can be applied to at least one of the interior surface and exterior surface of a substrate. The polymer-containing binder material can be applied onto the catalyst, and subsequently, the alkane-containing top coat can be applied onto the coating or layer formed by the polymer-containing binder material. The top coat can be applied while the polymer-containing binder coating is still tacky, e.g., prior to drying. This coating composition includes the ingredients in the amounts listed below, and can be commercially Obtained under the trade name NeverWet™ from Ross Technology, LLC.

IV. CATALYST-PART A

| Ingredient | % by Wt |
|---|---|
| n-Butyl Acetate | 25 |
| Hexamethylene Diisocyanate Polymer | 75 |
| Hexamethylene Diisocyanate | 0.7 max |

IV. POLYMER-CONTAINING BINDER MATERIAL-PART B

| Ingredient | % by Wt |
|---|---|
| Toluene | 6 |
| Methyl Ethyl Ketone | 18 |
| Cyclohexanone | 33 |
| Isopropyl Acetate | 5 |
| n-Butyl Acetate | 20 |
| Polymeric Resin | 11 |
| Polymeric Particles | 7 |

IV. ALKANE-CONTAINING TOP COAT

| Ingredient | % by Wt |
|---|---|
| Hexane | 93-36 |
| Silicones reaction with silica | 4-7 |

In certain embodiments, a single-coat coating composition may be employed. This composition is applied to at least one of the interior surface and exterior surface of a substrate, e.g., housing, as a single coating composition to form a one-layer coating. This composition includes the ingredients in the amounts listed below, and can be obtained under the trade name E-Coat formulations from Ross Nanotechnology, LLC.

V. SINGLE COAT

| Ingredient | % by Wt |
|---|---|
| n-Propanol | 95 |
| Silica | 2 |
| Proprietary Additive | 1 |
| Proprietary Polymer | 2 |

### EXAMPLES

The below examples include recent test data of abrasion (Tabor testing), corrosion testing and tensile testing of coating compositions in accordance with the disclosed concept on neoprene material samples.

### Chemical Resistance

To demonstrate the chemical resistance of superhydrophobic coatings, a series of soak tests were performed using a 100:1 ratio of water and Smokehouse degreaser with coated coupons for the NeverWet™ I Flex (above identified) and the NeverWet™ NuO, with and without acetone (above identified), from Ross Technology, LLC to measure the initial and after--soak contact angles of the coatings at specific intervals over the course of the testing conducted. For specific product applications, back of the envelope calculations were used to simulate “exposed soak time” in the real world using feedback from end customers. Additional soak testing was conducted up to 780 minutes (13 hours) which was calculated to be the equivalent of 12 years of in-field exposure, to demonstrate no loss of superhydrophobicity (no change in contact angle measurements) after chemical soak duration. Earlier data collected using the NeverWet™ I formulation (above identified) and NeverWet™ NuO without acetone formulation (above identified), suggests no change in contact angle measurements up to 13 hours, and in the case of the I formulation, up to 48.5 hours of soaking was observed with no change in contact angle.

### Abrasion Testing

Abrasion (tabor) testing was performed on several samples in accordance with ASTM D4060 to determine the number of cycles required to 1) lose the properties of superhydrophobicity and 2) reveal initial indications of the metal substrate below. See below Table I. Samples were tested at a load of a 1,000 g using a CS-10 wheel on a standard tabor testing machine. Contact angle measurements were performed using a standard goniometer measurement system. The INeverWet™ I-Flex formulation (above-identified) performed in a similar fashion as compared to other paints, such as electro coat or epoxy paint in terms of the number of cycles before bare metal exposure and wear factor. However, as to the number of cycles before one could visually observe the loss of superhydrophobicity, there was a distinct difference between the NeverWet™ NuO formulation (above identified) and NeverWet™ I-Flex formulation (above identified). This was due to the overall make-up of each coating system.

TABLE I

| | | Avg. # of Cycles | | Avg. # of Cycles | Avg. |
|---|---|---|---|---|---|
| | Avg. Coating | Before Loss of | Avg. Weight | Before Bare | Wear |
| Coating | Thickness (mil) | Superhydrophobicity | Loss (g) | Metal Exposure | Factor |
| I-Flex-Coat | 5.5 | 10.0 | 0.036 | 1000* | 36 |
| NuO-Coat | 3.9 | 75.0 | 0.148 | 455 | 362 |
| Epoxy Paint | 6.6 | — | 0.225 | 1100 | 444 |
| E-Coat Paint | 1 | — | 0.061 | 763 | 81 |

*test stopped at 1000 taber cycles

### Corrosion Testing

Corrosion testing of the NeverWet™ I-Flex (above identified) and NeverWet™ NuO formulations (above-identified) showed that these coatings can achieve up to 1,200 hours of performance under salt fog testing in accordance with ASTM B-117 methods and showed superior performance in terms of creep from scribe, blister or rust appearance in accordance with ASTM D1645, D714, and D610 in instances where the coating was used as a standalone coating on substrate material or as a secondary protective layer to currently used conformal -outings as shown in Table 11 below. In most cases, conformal paints require only 600 hours performance in salt fog conditions. The superhydrophobic coatings provided superior performance in terms of ability to prevent corrosion creep from scribe, adequate adhesion to the substrate material and effective ability to prevent salt fog intrusion under the coating.

TABLE II

| | Creep from Scribe | Blister Rating | Rust Rating |
|---|---|---|---|
| I-Flex | 10.0 | 10.0 | 10.0 |
| NuO w/o | 7.0 | 10.0 | 10.0 |
| acetone | | | |
| NuO | 9.5 | 10.0 | 10.0 |

### Ductility Performance

Prior tensile testing of superhydrophobic coated neoprene coupons showed the NeverWet™ I formulation (above identified) caused the coupons to respond in a brittle manner. Tensile testing (using an MTS tensile tester) of the NeverWet™ I-Flex formulation (above identified) showed the coated coupons to respond in a ductile manner. The NeverWet™ NuO and NuO without acetone formulations (above identified) were also tested to demonstrate similar ductility behavior as a baseline, noncoated coupon. The NeverWet™ I-Flex formulation provided a 71% reduction in stiffness when comparing the NeverWet™ I thrmulation to the NeverWet™ I-Flex formulation (above identified). This was a result of modification of the chemicals present within the binder system (part B of the formulation) for the NeverWet™ I-Flex formulations (above identified) when compared to the NeverWet™ I formulation (above identified). Also, an additional factor to this test was that the coupons were subjected to chemical soaking prior to performing the tensile testing. This was added to better demonstrate the repellency nature of the superhydrophobic coatings where no performance change in gasket material was observed from a non-soaked coupon versus a coupon soaked for 800 consecutive minutes in a 100:1.

While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the full breadth of the claims appended and any and all equivalents thereof.

What is claimed is:

1. A method of at least partially coating a component in an electrical system, comprising:
obtaining an uncoated component having an interior surface and an exterior surface; and
at least partially applying to at least one of the interior surface and the exterior surface of the uncoated component a coating composition to form a coating thereon, said coating composition comprising polyurethane.

2. The method of claim 1, wherein the component is selected from the group consisting of a network protector housing and safety switch housing.

3. The method of claim 1, wherein the coating composition is selected from the group consisting of superhydrophobic coating compositions, oleophobic coating compositions, and combinations thereof.

4. The method of claim 1, wherein said coating is capable to produce at least one of the effects selected from the group consisting of reducing or precluding the ingress of one or more of water and oil in said component, reducing or precluding water wetting in said component, and exhibiting self-cleaning properties.

5. The method of claim 1, wherein the coating composition is solvent-based.

6. The method of claim 1, wherein the coating composition is water-based.

7. The method of claim 1, wherein the coating composition comprises a binder material and nanoparticles.

8. The method of claim 7, wherein the nanoparticles are dispersed in the binder material.

9. The method of claim 7, wherein the coating comprises a basecoat comprising binder material and a topcoat applied to the basecoat, the topcoat comprising nanoparticles.

10. The method of claim 9, wherein the basecoat comprises nanoparticles.

11. The method of claim 9, wherein the basecoat does not include the presence of nanoparticles.

12. An at least partially coated component in an electrical system, comprising:
an uncoated component; and
a coating composition comprising polyurethane at least partially applied to at least one of the interior surface and the exterior surface to form a coating thereon.

13. The component of claim 12, wherein the component is selected from the group consisting of a network protector housing and safety switch housing.

14. The component of claim 12, the coating composition comprises a binder material and nanoparticles.

15. The method of claim 14, wherein the nanoparticles are dispersed in the binder material.

16. The method of claim 14, wherein the coating comprises a basecoat comprising binder material and a topcoat applied to the basecoat, the topcoat comprising nanoparticles.

17. The method of claim 16, wherein the basecoat comprises nanoparticles.

18. The method of claim 16, wherein the basecoat does not include the presence of nanoparticles.

19. An apparatus comprising a housing having an interior surface and an exterior surface, the housing structured to enclose a component selected from the group consisting of a network protector and a safety switch, the housing having a coating formed on at least one of the interior surface and the exterior surface, the coating is formed from a coating composition comprising polyurethane.

20. The apparatus of claim 19, wherein the coating comprises a basecoat comprising binder material and a topcoat applied to the basecoat, the topcoat comprising nanoparticles.
